(19) United States
(12) Patent Application Publication
(10) Pub. No.: US 2012/0043616 A1
(43) Pub. Date: Feb. 23, 2012

(54) SUB WORD LINE DRIVER AND APPARATUSES HAVING THE SAME

(75) Inventors: Jae Young Lee, Hwaseong-si (KR); Hyang Ja Yang, Seoul (KR)

(73) Assignee: SAMSUNG ELECTRONICS CO., LTD., Suwon-si (KR)

(21) Appl. No.: 13/206,933

(22) Filed: Aug. 10, 2011

(30) Foreign Application Priority Data
Aug. 18, 2010 (KR) 10-2010-0079816

(51) Int. Cl. H01L 27/092; H01L 23/52

(52) U.S. Cl. 257/369; 257/773; 257/E27.062; 257/E23.141

(57) ABSTRACT

A sub word line driver is provided. The sub word line driver includes a first layer including a plurality of first pads disposed in a first line of a first direction, a plurality of second pads arranged in a second line of the first direction, and two first word lines arranged twisted twice in the first direction between the plurality of first pads and the plurality of second pads, each of the two first word lines being connected to a corresponding pad among the plurality of second pads; and a second layer, which is formed at a lower part of the first layer, and includes the second layer including a plurality of third pads, each the plurality of third pads each being embodied disposed at each corresponding a position corresponding to a pad from among one of the plurality of first pads and the plurality of second pads.

### CROSS-REFERENCE TO RELATED APPLICATIONS

This application claims priority under 35 U.S.C. §119 to Korean Patent Application No. 10-2010-0079816 filed on Aug. 18, 2010 in the Korean Intellectual Property Office (KIPO), the entire contents of which are hereby incorporated by reference.

### BACKGROUND

Some example embodiments relate to a sub word line driver (SWD) of a memory device and apparatuses having the same.

A memory cell array of a memory device is divided by a plurality of banks, and each of the plurality of banks is divided into a plurality of memory blocks. Additionally, each of the plurality of memory blocks includes a plurality of sub array blocks. A divided word line driver structure, which arranges each of a plurality of sub word line drivers between the plurality of sub array blocks for reducing signal delay caused by load of the word line as a word line gets longer in a high-density memory cell array, is adopted.

### SUMMARY

Some example embodiments provide a new sub word line driver which may solve a layout problem of a sub word line driver caused by a word line pitch decrease, and apparatuses having the same.

Some example embodiments are directed to a sub word line driver, including a plurality of first pads arranged in a first line of a first direction, a plurality of second pads disposed in a second line of the first direction, a first layer including two first word lines disposed twisted twice in the first direction between the plurality of first pads and the plurality of second pads, each of the two first word lines being connected to a corresponding pad among the plurality of second pads, and a second layer formed at a lower part of the first layer, the second layer including a plurality of third pads, the plurality of pads each being disposed at a position corresponding to a pad from among one of the plurality of first pads and the plurality of second pads.

According to some example embodiments, the first layer further includes a plurality of fourth pads each formed at an opposite position to each of the plurality of first pads and two second word lines disposed twisted twice in the first direction between the plurality of second pads and the plurality of fourth pads. The second layer further includes a plurality of fifth pads each formed at positions corresponding to each of the plurality of fourth pads.

According to some example embodiments, the two second word lines are connected to a corresponding pad among the plurality of second pads, respectively.

According to some example embodiments, the plurality of third pads are each connected to at least one transistor from among a plurality of first conductive transistors and a plurality of second conductive transistors. Each pad of a first group among the plurality of first pads is connected to a first electrode of each of a plurality of first conductive transistors via a corresponding one of the plurality of third pads, each pad of a second group among the plurality of first pads is connected to a first electrode of each of a plurality of second conductive transistors via a corresponding one of the plurality of third pads, each pad of a third group among the plurality of second pads is connected to a second electrode of each of the plurality of first conductive transistors, and each pad of fourth group among the plurality of second pads is connected to a second electrode of each of the plurality of second conductive transistors.

According to some example embodiments, each of the plurality of first conductive transistors is one of a PMOS transistor and an NMOS transistor, and each of the plurality of second conductive transistors is the other of the PMOS transistor and the NMOS transistor.

According to some example embodiments, the first electrode of each of the plurality of first conductive transistors and second conductive transistors is a source electrode, and the second electrode of each of the plurality of first conductive transistors and second conductive transistors is a drain electrode.

Some example embodiments are directed to a semiconductor device, including a plurality of sub arrays and a plurality of sub word line drivers each disposed between the plurality of sub arrays. Each of the plurality of sub word line drivers includes a plurality of first pads disposed in a line of a first direction, a plurality of second pads disposed in a line of the first direction, a first layer including two first word lines disposed twisted twice in the first direction between the plurality of first pads and the plurality of second pads, each of the two first word lines being connected to a corresponding pad among the plurality of second pads, and a second layer formed at a lower part of the first layer, the second layer including a plurality of third pads, each of the plurality of third pads being disposed at a position corresponding to a pad from among one of the plurality of first pads and the plurality of second pads.

Some example embodiments are directed to a semiconductor system, including the semiconductor device and a processor for controlling an operation of the semiconductor device. The semiconductor system is a mobile communication device.

Some example embodiments are directed to a memory module, including the semiconductor device and a semiconductor substrate where the semiconductor device is mounted.

Some example embodiments are directed to a semiconductor system, including a memory module where the semiconductor device is mounted, a board including a socket where the memory module may be inserted, and a processor for controlling an operation of the semiconductor device through the socket. The memory module is a single in-line memory module (SIMM) or a dual in-line memory module (DIMM). The semiconductor system is a personal computer. According to some example embodiments, a sub word line driver includes a first layer including a plurality of first pads disposed in a first line of a first direction, a plurality of second pads arranged in a second line of the first direction, and at least two first word lines arranged along the first direction and in between the plurality of first pads and the plurality of second pads, the at least two first word lines being twisted at least once at a position in between the plurality of first pads and the plurality of second pads.

According to some example embodiments, the at least two first word lines are twisted such that (1) for a first portion of a length of the at least two first word lines, a first one of the at least two first word lines is in between the second pads and a second one of the at least two first word lines, and (2) for a second portion of the length of the at least two first word lines, the second one of the at least two first word lines is in between the second pads and the first one of the at least two first word lines.

According to some example embodiments, the at least two first word lines are each connected to at least one corresponding pad among the plurality of second pads.

According to some example embodiments a second layer formed at a lower part of the first layer, the second layer including a plurality of third pads, each of the plurality of third pads being disposed at a position corresponding to one of the first and second pads of the first layer.

According to some example embodiments, the sub word line driver of claim 24 wherein the first layer further comprises a plurality of fourth pads in a third line of the first direction; and at least two second word lines arranged along the first direction and in between the plurality of second pads and the plurality of fourth pads, the at least two second word lines being twisted at least once.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 shows a memory device including a sub word line driver block according to an example embodiment;

FIG. 2 shows a block diagram of the sub word line driver block illustrated in FIG. 1;

FIG. 3 shows a circuit diagram of the sub word line driver block illustrated in FIG. 2;

FIG. 4 shows a transistor layout layer of a plurality of sub word line driver blocks illustrated in FIG. 3;

FIG. 5 shows an interconnection line layer for the transistor layout layer illustrated in FIG. 4;

FIG. 6 shows a memory module including the memory device illustrated in FIG. 1;

FIG. 7 shows a block diagram of a computer including the memory module illustrated in FIG. 5;

FIG. 8 shows an example embodiment of a memory system including the memory device illustrated in FIG. 1;

FIG. 9 shows another example embodiment of a memory system including the memory device illustrated in FIG. 1; and

FIG. 10 is a flowchart explaining a layout method of a sub word line driver according to an example embodiment.

### DETAILED DESCRIPTION OF THE PREFERRED EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

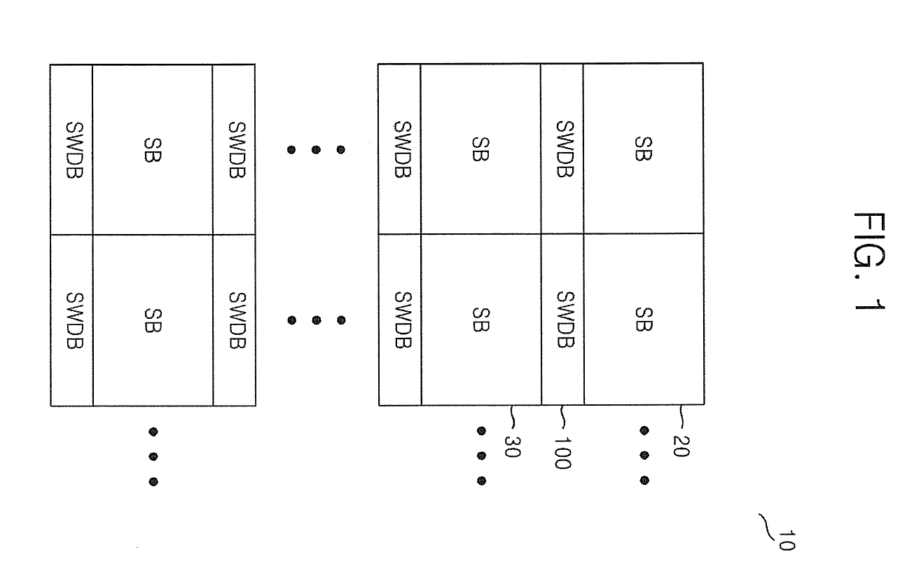

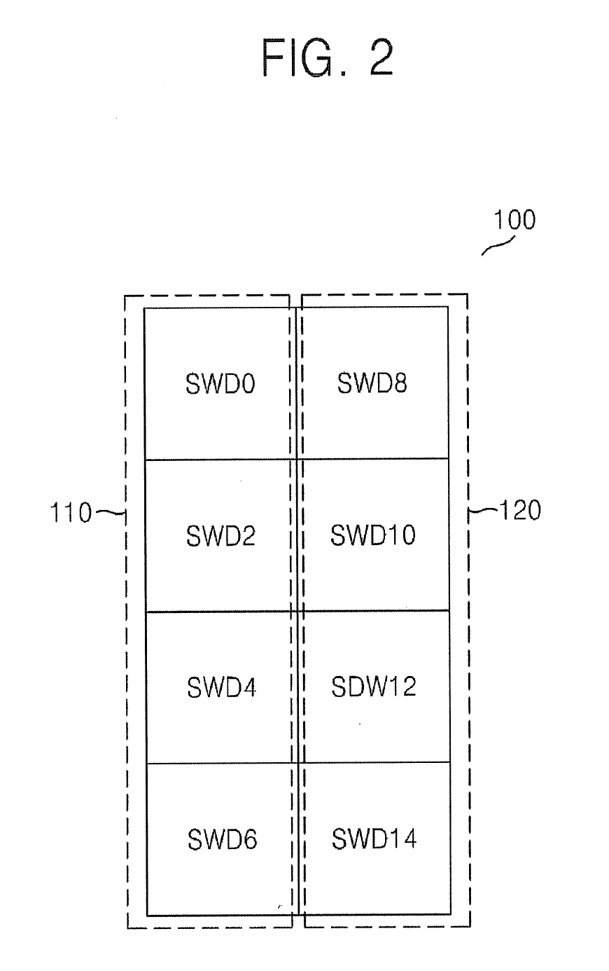

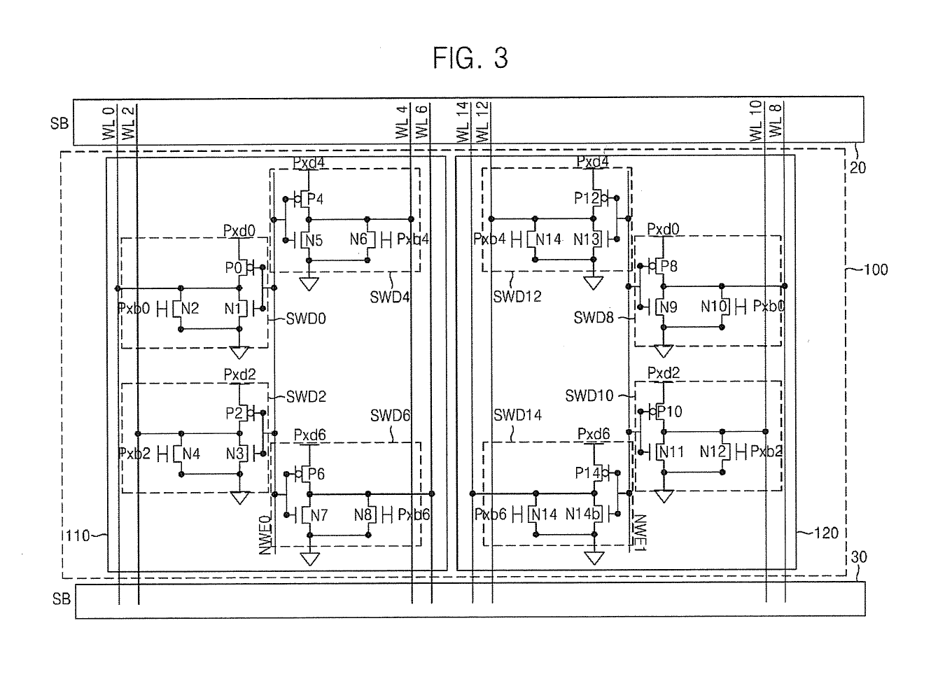

FIG. 1 shows a memory device including a sub word line driver block according to an example embodiment, FIG. 2 shows a block diagram of the sub word line driver block illustrated in FIG. 1, and FIG. 3 shows a circuit diagram of the sub word line driver block illustrated in FIG. 2.

Referring to FIGS. 1 to 3, a memory device 10 includes a plurality of sub array blocks SB 20 and 30, and a plurality of sub word line driver blocks SWDB 100 disposed between the plurality of sub array blocks 20 and 30.

Each of the plurality of sub array blocks SB 20 and 30 includes a plurality of memory cells, and each of the plurality of memory cells is connected to each of a plurality of word lines and each of a plurality of bit lines.

The sub word line driver block SWDB 100 includes a first driver block 110 and a second driver block 120.

The first driver block 110 includes a plurality of sub word line drivers SWD0, SWD2, SWD4 and SWD6, and each of the plurality of sub word line drivers SWD0, SWD2, SWD4 and SWD6 may supply a driving voltage to each of a plurality of word lines WL0, WL2, WL4 and WL6 embodied in a sub array block 20.

The second driver block 120 includes a plurality of sub word line drivers SWD8, SWD10, SWD12 and SWD14, and each of the plurality of sub word line drivers SWD8, SWD10, SWD12 and SWD14 may supply a driving voltage to each of a plurality of word lines WL8, WL10, WL12 and WL14 embodied in the sub array block 20.

Referring to FIGS. 2 and 3 again, a first sub word line driver SWD0 of the first driver block 110 includes a first P channel transistor P0 and a first N channel transistor N1, which are connected in series between a first supply Pxd0 and a ground. In addition, the first sub word line driver SWD0 includes a second N channel transistor N2 connected between a common node of the first P channel transistor P0 and the first N channel transistor N1 and the ground.

A second sub word line driver SWD2 includes a second P channel transistor P2 and a third N channel transistor N3, which are connected in series between a second supply Pxd2 and a ground. Additionally, the second sub word line driver SWD2 includes a fourth N channel transistor N4 connected between a common node of the second P channel transistor P2 and the third N channel transistor N3 and the ground.

A third sub word line driver SWD4 includes a third P channel transistor P4 and a fifth N channel transistor N5, which are connected in series between a third supply Pxd4 and a ground. Additionally, the third sub word line driver SWD4 includes a sixth N channel transistor N6 connected between a common node of the third P channel transistor P4 and the fifth N channel transistor N5 and the ground.

A fourth sub word line driver SWD6 includes a fourth P channel transistor P6 and a seventh N channel transistor N7, which are connected in series between a fourth supply Pxd6 and a ground. Additionally, the fourth sub word line driver SWD6 includes an eighth N channel transistor N8 connected between a common node of the fourth P channel transistor P6 and the seventh N channel transistor N7 and a ground.

Each gate of a plurality of P channel transistors P0, P2, P4 and P6 is connected to a first input signal line NWE0, and each gate of a plurality of N channel transistors N1, N3, N5 and N7 is connected to the first input signal line NWE0. Furthermore, each gate of a plurality of N channel transistors N2, N4, N6 and N8 is connected to each of a plurality of third input signal lines Pxb0, Pxb2, Pxb4 and Pxb6.

A common node of a first P channel transistor P0 and a first N channel transistor N1 is connected to a first word line WL0, a common node of a second P channel transistor P2 and a third N channel transistor N3 is connected to a second word line WL2, a common node of a third P channel transistor P4 and a fifth N channel transistor N5 is connected to a third word line WL4, and a common node of a fourth P channel transistor P6 and a seventh N channel transistor N7 is connected to a fourth word line WL6.

A second driver block 120 has a structure similar to a structure of the first driver block 110 except that each gate of a plurality of P channel transistors P8, P10, P12 and P14 is connected to a second input signal line N′WE1, so that its detailed explanation is omitted.

Each of a plurality of supplies Pxd0, Pxd2, Pxd4 and Pxd6 may generally supply a voltage of a higher level than an internal supply voltage used in a memory device.

By an input signal coding, one of the plurality of supplies Pxd0, Pxd2, Pxd4 and Pxd6 supplies a voltage to a corresponding one of a plurality of P channel transistors P0, P2, P4, P6, P8, P10, P12 and P14.

Each of a plurality of input signal lines NWE0 and NWE1 is a line for supplying an input signal for driving each of a plurality of sub word line drivers SWD0, SWD2, SWD4 and SWD6 embodied in a first driver block 110 and each of a plurality of sub word line drivers SWD8, SWD10, SWD12 and SWD14 embodied in a second driver block 120.

Each of a plurality of third input signal lines Pxb0, Pxb2, Pxb4 and Pxb6 is a line for supplying a signal for pre-charging each of a plurality of word lines WL0, WL2, WL4 and WL6 or WL8, WL10, WL12 and WL14 through a corresponding N channel transistor.

Each operation of a plurality of sub word line drivers SWD0, SWD2, SWD4, SWD6, SWD8, SWD10, SWD12 and SWD14 is as follows.

For convenience of explanation, a first sub word line driver SWD0 will be explained in detail. Each of sub word lines drivers SWD2, SWD4, SWD6, SWD8, SWD10, SWD12 and SWD14 may have the same operation as first sub word line driver SWD0.

In the first sub word line driver SWD0, when each input signal of a first input signal line NWE0 and a third input signal line Pxb0 is at a low level, a voltage of a first supply Pxd0 is supplied to a first word line WL0.

When at least one of an input signal of a first input signal line NWE0 and an input signal of a third input signal line Pxb0 is at a high level, the first word line WL0 becomes a ground level.

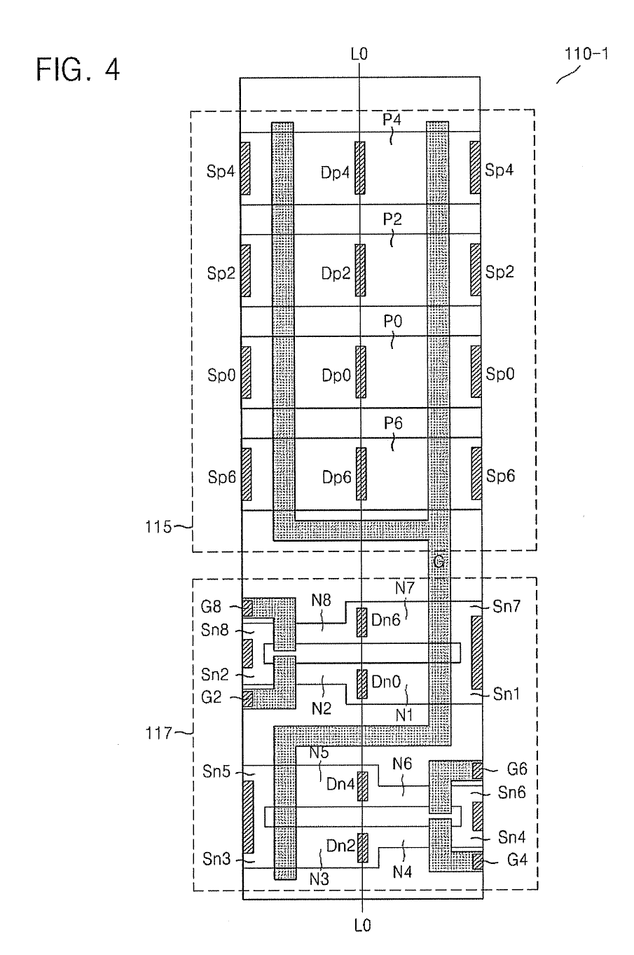

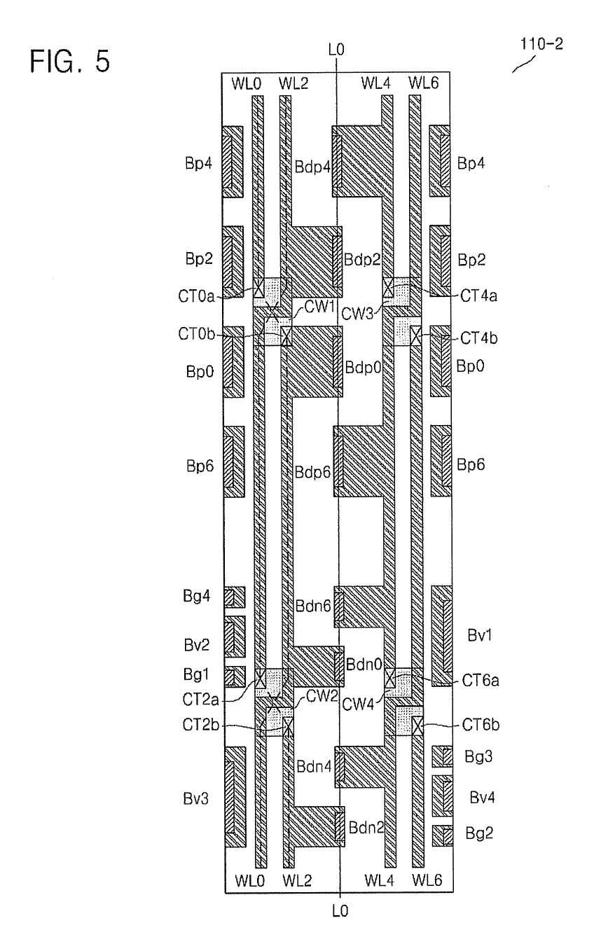

FIG. 4 shows a transistor layout layer of a plurality of sub word line driver blocks illustrated in FIG. 3, and FIG. 5 shows an interconnection line layer for the internal transistor layout layer illustrated in FIG. 4.

For convenience of explanation, a transistor layout layer 110-1 and an interconnection line layer 110-2 are illustrated separately in FIGS. 4 and 5. However, the interconnection line layer 110-2 is actually stacked on an upper side of the transistor layout layer 110-1.

Since layouts of internal transistors of the first driver block 110 and the second driver block 120 are substantially the same, only sub word line drivers SWD0, SWD2, SWD4 and SWD6 of the first driver block 110 are explained in FIGS. 4 and 5 for convenience of explanation.

Referring to FIGS. 2 to 5, a transistor layout layer 110-1 includes a P channel transistor layout region 115 and an N channel transistor layout region 117.

In the P channel transistor layout region 115, a third P channel transistor P4, a second P channel transistor P2, a first P channel transistor P0 and a fourth P channel transistor P6 are arranged successively in a first direction e.g., a word line direction.

Each of the third P channel transistor P4, the second P channel transistor P2, the first P channel transistor P0 and the fourth P channel transistor P6 is a two-finger transistor.

In the third P channel transistor P4, sources Sp4 are formed at both a right and a left side, a drain Dp4 is formed in the center, and each gate line G is disposed between each of the sources Sp4 and the drain Dp4.

A source, a drain and a gate as used herein are synonymous with, and may be referred to as, a source electrode, a drain electrode and a gate electrode, respectively.

In a second P channel transistor P2, sources Sp2 are formed at both a right and a left side, a drain Dp2 is formed in the center, and each gate line G is disposed between each of the sources Sp2 and the drain Dp2. In a first P channel transistor P0, sources Sp0 are formed at both a right and a left side, a drain Dp0 is formed in the center, and each gate line G is disposed between each of the sources Sp0 and the drain Dp0. In a fourth P channel transistor P6, sources Sp6 are formed at both a right and a left side, a drain Dp6 is formed in the center, and each gate line G is disposed between each of the sources Sp6 and the drain Dp6.

Here, each drain Dp0, Dp2, Dp4 and Dp6 of the plurality of P channel transistors P0, P2, P4 and P6 may be located on a reference line L0.

The reference line L0 is a virtual line passing by the center of a transistor layout layer 110-1 or an interconnection line layer 110-2 in the first direction, e.g., a word line direction. Therefore, each characteristic of the plurality of P channel transistors P0, P2, P4 and P6 is very similar.

In an N channel transistor layout region 117, a pair of an eighth N channel transistor N8 and a seventh N channel transistor N7, a pair of a second N channel transistor N2 and a first N channel transistor N1, a pair of a fifth N channel transistor N5 and a sixth N channel transistor N6, and a pair of a third N channel transistor N3 and a fourth N channel transistor N4 are successively arranged.

A source Sn8 of the eighth N channel transistor N8 is formed at a left edge and a source Sn7 of the seventh N channel transistor N7 is formed at a right edge. The eighth N channel transistor N8 and the seventh N channel transistor N7 share a drain Dn6.

A source Sn2 of the second N channel transistor N2 is formed at a left edge and a source Sn1 of the first N channel transistor N1 is formed at a right edge. The second N channel transistor N2 and the first N channel transistor N1 share a drain Dn0.

Here, a source Sn8 of the eighth N channel transistor N8 and a source Sn2 of the second N channel transistor N2 are connected to each other, and a source Sn7 of the seventh N channel transistor N7 and a source Sn1 of the first N channel transistor N1 are connected to each other.

A source Sn5 of the fifth N channel transistor N5 is formed at a left edge and a source Sn6 of the sixth N channel transistor N6 is formed at a right edge. The fifth N channel transistor N5 and the sixth N channel transistor N6 share a drain Dn4.

A source Sn3 of the third N channel transistor N3 is formed at a left edge and a source Sn4 of the fourth N channel transistor N4 is formed at a right edge. The third N channel transistor N3 and the fourth N channel transistor N4 share a drain Dn2.

Here, a source Sn5 of the fifth N channel transistor N5 and a source Sn3 of the third N channel transistor N3 are connected to each other, and a source Sn6 of the sixth N channel transistor N6 and a source Sn4 of the fourth N channel transistor N4 are connected to each other.

In addition, each of the seventh N channel transistor N7, the first N channel transistor N1, the fifth N channel transistor N5 and the third N channel transistor N3 has a common gate line G. A first input signal line NWE0 is connected to the common gate line G.

A gate G8 is formed between a source Sn8 and a drain Dn6 in the eighth N channel transistor N8, a gate G2 is formed between a source Sn2 and a drain Dn0 in the second N channel transistor N2, a gate G6 is formed between a source Sn6 and a drain Dn4 in the sixth N channel transistor N6, and a gate G4 is formed between a source Sn4 and a drain Dn2 in the fourth N channel transistor N4.

Each drain Dn0, Dn2, Dn4 and Dn6 like the drains Dp0, Dp2, Dp4 and Dp6 of the plurality of P channel transistor P0, P2, P4 and P6, may all be formed on the reference line L0.

According to an example embodiment, a second P channel transistor P2, a third P channel transistor P4, a fourth P channel transistor P6 and a first P channel transistor P0 may be arranged successively in the first direction in a P channel transistor layout region 115. Further, a seventh N channel transistor N7, a first N channel transistor N1, a third N channel transistor N3 and a fifth N channel transistor N5 may be arranged successively in an N channel transistor layout region 117.

An interconnection line layer 110-2 of FIG. 5 includes a plurality of first pad pairs Bp0, Bp2, Bp4 and Bp6, a plurality of second pads Bv1, Bv2, Bv3 and Bv4, a plurality of third pads Bg1, Bg2, Bg3 and Bg4 and a plurality of word lines WL0, WL2, WL4 and WL6.

Each of the plurality of first pads Bp0, Bp2, Bp4 and Bp6 is disposed so that it may be connected to each corresponding source Sp0, Sp2, Sp4 and Sp6 of a plurality of P channel transistors P0, P2, P4 and P6. For example, each of the plurality of first pad pairs Bp0, Bp2, Bp4 and Bp6 is disposed in the first direction in an order of a third pad pair Bp4, a second pad pair Bp2, a first pad pair Bp0 and a fourth pad pair Bp6.

Each of the plurality of second pads Bv1, Bv2, Bv3 and Bv4 is disposed so that it may be connected to each corresponding source Sn1, Sn2, Sn3 or Sn4 of a plurality of N channel transistors N1, N2, N3 and N4. In addition, each of the plurality of second pads Bv1, Bv2, Bv3 and Bv4 is disposed so that it may be connected to each corresponding source Sn7, Sn8, Sn5 and Sn6 of a plurality of N channel transistors N7, N8, N5, and N6. P0, P2, P4 and P6. Each of a plurality of third pads Bg1, Bg2, Bg3 and Bg4 is disposed so that it may be connected to each corresponding gate G2, G4, G6 and G8 of a plurality of N channel transistors N2, N4, N6 and N8.

Each of a plurality of word lines WL0, WL2, WL4 and WL6 includes each of a plurality of fourth pads Bdp0, Bdp2, Bdp4 and Bdp6 so that it may be connected to each corresponding drain Dp0, Dp2, Dp4 and Dp6 of a plurality of P channel transistors P0, P2, P4 and P6. Each of the plurality of word lines WL0, WL2, WL4 and WL6 is also connected to each of the drains Dn0, Dn2, Dn4 and Dn6 through each of a plurality of fifth pads Bdn0, Bdn2, Bdn4 and Bdn6.

For example, a first word line WL0 is connected to a drain Dp0 of a first P channel transistor P0 through a pad Bdp0 and connected to each drain Dn0 of a first N channel transistor N1 and a second N channel transistor N2 through a pad Bdn0.

In the same manner, a second word line WL2 is connected to a drain Dp2 of a second P channel transistor P2 through a pad Bdp2 and connected to each drain Dn2 of a third N channel transistor N3 and a fourth N channel transistor N4 through a pad Bdn2.

A third word line WL4 is connected to a drain Dp4 of a third P channel transistor P4 through a pad Bdp4 and connected to each drain Dn4 of a fifth N channel transistor N5 and a sixth N channel transistor N6 through a pad Bdn4. Furthermore, a fourth word line WL6 is connected to a drain Dp6 of a fourth P channel transistor P6 through a pad Bdp6 and connected to a drain Dn6 of each of a seventh N channel transistor N7 and an eighth N channel transistor N8 through a pad Bdn6.

Each of fourth pads Bdp0, Bdp2, Bdp4 and Bdp6 and each of fifth pads Bdn0, Bdn2, Bdn4 and Bdn6 are all disposed in a line on the reference line L0.

As each of the plurality of fourth pads Bdp0, Bdp2, Bdp4 and Bdp6 and each of the plurality of fifth pads Bdn0, Bdn2, Bdn4 and Bdn6 are all arranged in a line on the reference line L0, the number of maximum word lines existing between two corresponding pads Bp4 and Bdp4, Bdp2 and Bp2, Bdp0 and Bp0, Bp6 and Bdp6, Bv2 and Bdn6, and Bv3 and Bdn2 may be 2 or below.

As illustrated in FIG. 5, a first word line WL0 and a second word line WL2 are two-times twisted, and a third word line WL3 and a fourth word line WL4 are also two-times twisted.

Being twisted, as used herein, includes a case in which a pair of connection means CT0a and CT0b, CT2a and CT2b, CT4a and CT4b, and CT6a and CT6b are connected electrically through each of a plurality of connection means CW1, CW2, CW3 and CW4 as illustrated in FIG. 5.

That is, a first word line WL0 is connected electrically from an upper part to a lower part through a connection mean CW1 and a pair of connection means CT0a and CT0b, a second word line WL2 is connected electrically from an upper part to a lower part through a connection mean CW2 and a pair of connection means CT2a and CT2b, a third word line WL4 is connected electrically from an upper part to a lower part through a connection mean CW3 and a pair of connection means CT4a and CT4b, and a fourth word line WL6 is connected electrically from an upper part to a lower part through a connection mean CW4 and a pair of connection means CT6a and CT6b.

According to an example embodiment, the plurality of connection means CW1, CW2, CW3 and CW4 are connection units which may be embodied in, for example, a metal plate, a jumper and so on, respectively. Further, connection means CT0a and CT0b, CT2a and CT2b, CT4a and CT4b, and CT6a and CT6b may be, for example, contacts on the connection units CW1, CW2, CW3 and CW4.

That is, as a first word line WL0 is twisted once so that it may be connected to a drain Dp0 connected to a pad Bdp0, a second word line WL2 is once twisted. And as the first word line WL0 is twisted once more so that it may be connected to a drain Dn2 connected to a pad Bdn2, the second word line is twisted once more.

Similarly, as a third word line WL4 is twisted once so that it may be connected to a drain Dp6 connected to a pad Bdp6, a fourth word line WL6 is also twisted once. As the third word line WL4 is twisted once more so that it may be connected to a drain Dn4 connected to a pad Bdn4, the fourth word line WL4 is also twisted once more.

As illustrated in FIGS. 4 and 5, a sub word line driver according to some example embodiments may have an efficient the sub word line driver layout even though a word line pitch becomes shrunk as two word lines at maximum is arranged between corresponding pads.

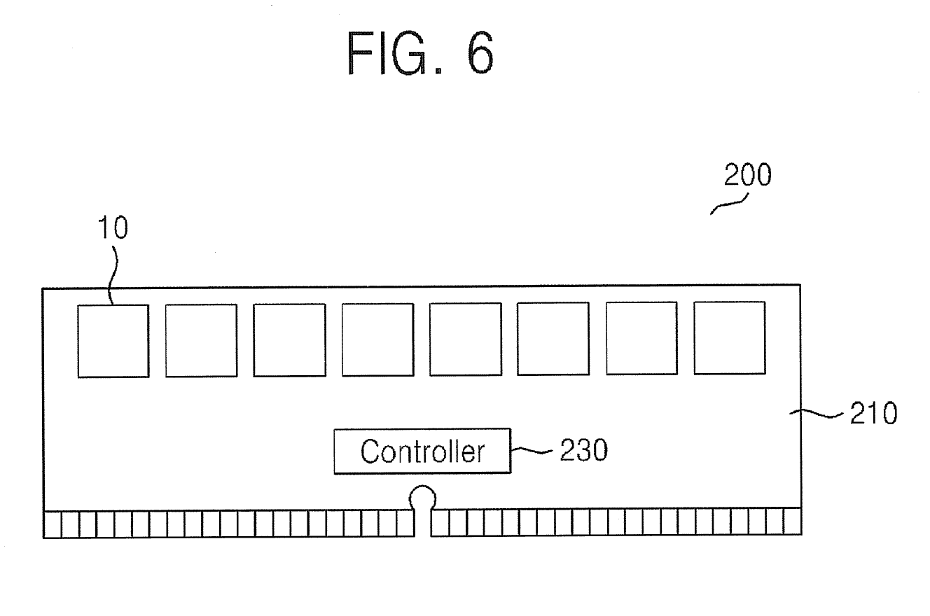

FIG. 6 shows a memory module including a memory device illustrated in FIG. 1. Referring to FIG. 6, a memory module 200 includes a semiconductor substrate 210 and a plurality of memory devices 10 mounted on the semiconductor substrate 210.

The plurality of memory devices 10 illustrated in FIG. 6 may be the same as semiconductor memory device 10 explained referring to FIGS. 1 to 5. According to an example embodiment, the memory module 200 may further include a controller 230 for controlling an operation of each of the plurality of memory devices 10. The memory module 200 may be embodied in a Single In-Line Memory (SIMM) or a Dual In-Line Memory Module (DIMM).

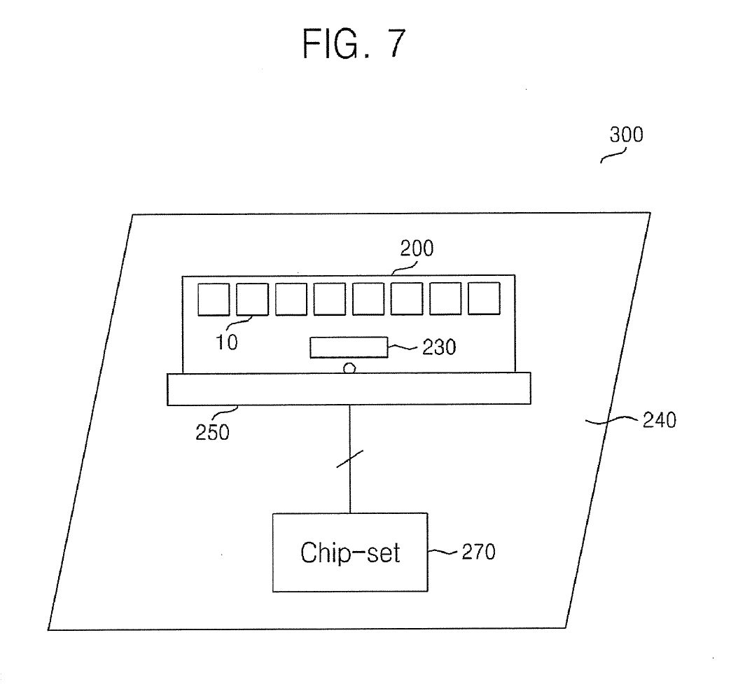

FIG. 7 shows a block diagram of a memory system including the memory module illustrated in FIG. 6. A memory system 300 which may be embodied in a computer system such as a personal computer (PC) or a mobile computing device includes a main board 240, a slot 250 mounted on the main board 240, a memory module 200 which may be inserted in the slot 250, and a processor, e.g., a chip-set 270, controlling an operation of each of the plurality of memory devices 10 mounted on the memory module 200 through the slot 250.

A chip-set 270 may exchange data with each of the plurality of memory devices 10 through a data bus. The memory system 300 may be embodied in a PC, a tablet PC or a laptop computer.

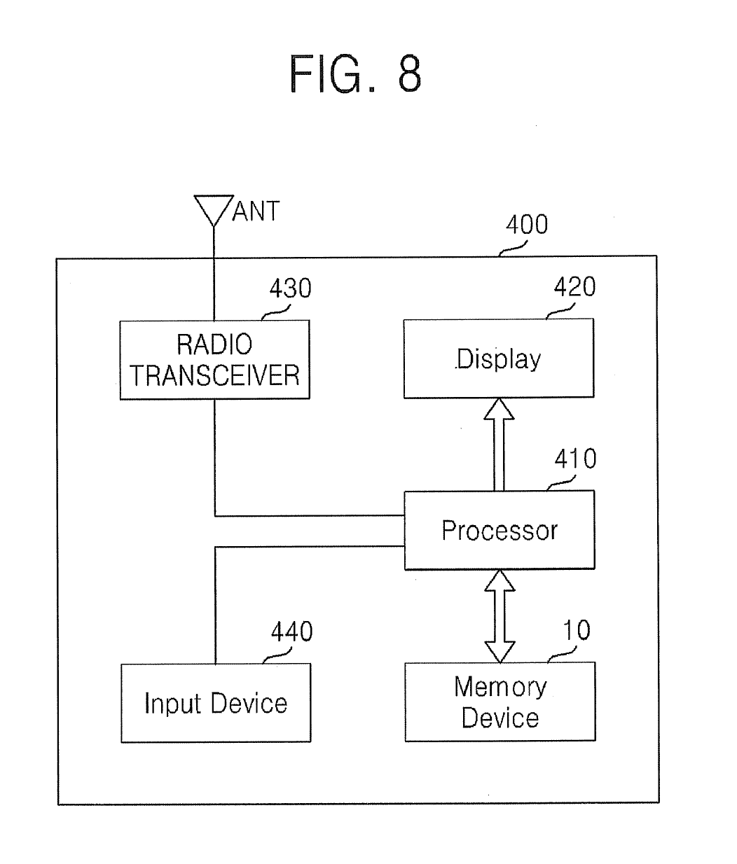

FIG. 8 shows an example embodiment of a memory system including a memory device illustrated in FIG. 1. Referring to FIG. 8, a memory system 400 which may be embodied in a cellular phone, a smart phone or a wireless internet device includes a memory device 10 and a processor 410 controlling a data processing operation of the memory device 10.

Data stored in the memory device 10 may be displayed through a display 420 under a control of the processor 410. A wireless transceiver 430 may transmit or receive wireless signals through an antenna ANT. For example, the wireless transceiver 430 may convert wireless signals received through an antenna ANT into signals which the processor 410 may process.

Accordingly, the processor 410 may process signals output from the wireless transceiver 430 and store them in the memory device 10 or display them through the display 420.

Additionally, the wireless transceiver 430 may convert signals output from the processor 410 into wireless signals and output the wireless signals through an antenna ANT.

An input device 440 is a device which may input control signals for controlling an operation of the processor 410 or data to be processed by the processor 410, and it may be embodied in a pointing device such as a touch pad and a computer mouse, a keypad, or a keyboard.

The processor 410 may control an operation of the display 420 so that data output from the memory device 10, data output from the wireless transceiver 430 or data output from the input device 440 may be displayed through the display 420.

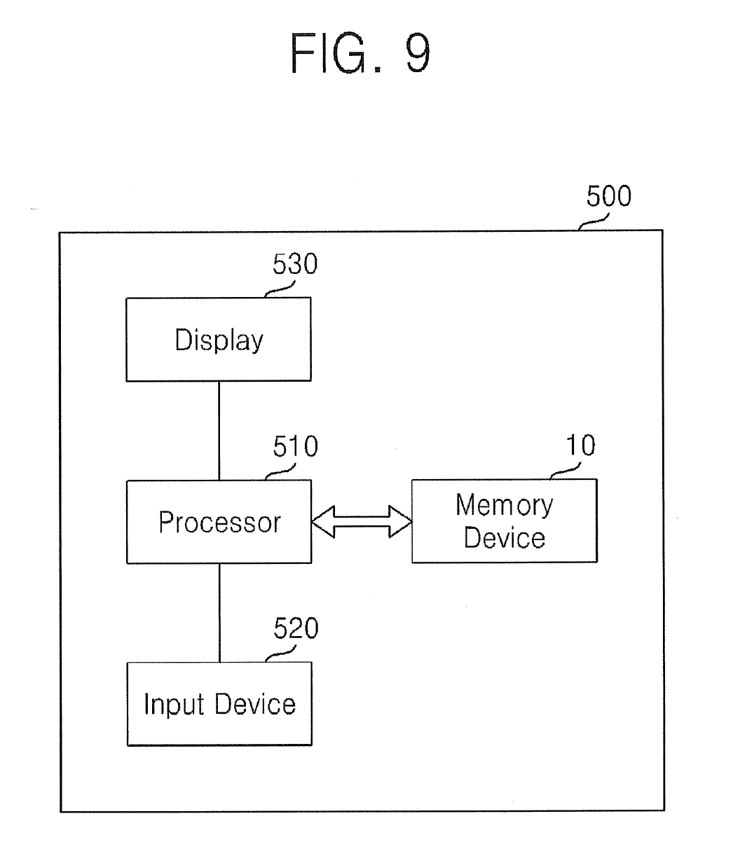

FIG. 9 shows another example embodiment of a memory system including a memory device illustrated in FIG. 1. Referring to FIG. 9, a memory system 500, which may be embodied in a data processing device such as a tablet computer, a net-book, an e-reader, a personal digital assistant (PDA), a portable multimedia player (PMP), a MP3 player or a MP4 player, includes a memory device 10 and a processor 510 which may control a data processing operation of the memory device 10.

The processor 510 may display data which is stored in a memory device 10 through a display 530 according to an input signal occurred by an input device 520. For example, the input device 520 may be embodied in a pointing device such as a touch pad or a computer mouse, a keypad or a keyboard.

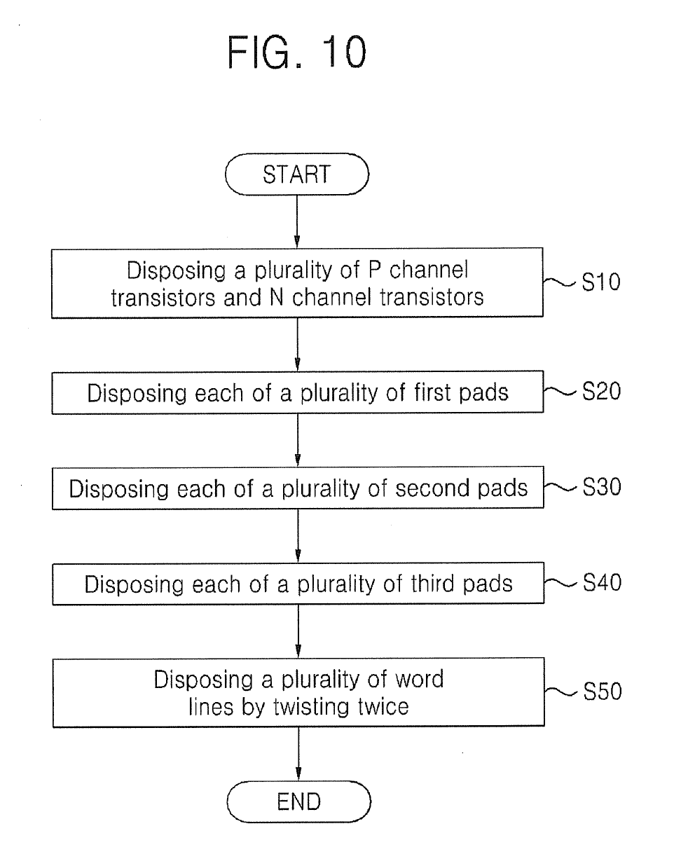

FIG. 10 shows a flowchart explaining a layout method of a sub word line driver according to an example embodiment.

Referring to FIGS. 4, 5 and 10, in step S10, a plurality of P channel transistor P0, P2, P4 and P6 and a plurality of N channel transistor N1-N8 are formed on a transistor layout layer 110-1, respectively.

In step S20, a plurality of first pads Bp0, Bp2, Bp4, Bp6, Bg1, Bg4, Bv2 and Bv3 are formed in a line of a first direction on an interconnection line layer 110-2 formed on the transistor layout layer 110-1, respectively. In step S30, a plurality of second pads Bp0, Bp2, Bp4, Bp6, Bg2, Bg3, Bv1 and Bv4 are formed in a line of the first direction on the interconnection line layer 110-2. In step S40, a plurality of third pads Bdp0, Bdp2, Bdp4, Bdp6, Bdn0, Bdn2, Bdn4 and Bdn6 are formed in a line of the first direction, respectively.

As illustrated in FIG. 5, a plurality of word lines WL0 and WL2, WL4 and WL6 are formed twisted twice.

A sub word line driver according to an example embodiment and apparatuses having the same may solve a layout problem of a sub word line driver caused by shrinking of a word line pitch.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

1. A sub word line driver comprising:
a first layer including a plurality of first pads disposed in a first line of a first direction, a plurality of second pads arranged in a second line of the first direction, and two first word lines arranged twisted twice in the first direction between the plurality of first pads and the plurality of second pads, each of the two first word lines being connected to a corresponding pad among the plurality of second pads; and
a second layer formed at a lower part of the first layer, the second layer including a plurality of third pads, the plurality of third pads each being disposed at a position corresponding to a pad from among one of the plurality of first pads and the plurality of second pads.

2. The sub word line driver of claim 1, wherein the first layer further includes
a plurality of fourth pads each formed at an opposite position to each of the plurality of first pads; and
two second word lines arranged twisted twice in the first direction between the plurality of second pads and the plurality of fourth pads, and
wherein the second layer further includes
a plurality of fifth pads formed at positions corresponding to each of the plurality of fourth pads,
wherein each of the two second word lines is connected to a corresponding pad among the plurality of second pads.

3. The sub word line driver of claim 1, wherein the plurality of third pads are each connected to at least one transistor from among a plurality of first conductive transistors and a plurality of second conductive transistors,
wherein each pad of a first group among the plurality of first pads is connected to a first electrode of each of the plurality of first conductive transistors via a corresponding one of the plurality of third pads,
wherein each pad of a second group among the plurality of first pads is connected to a first electrode of each of the plurality of second conductive transistors among via a corresponding one of the plurality of third pads,
wherein each pad of a third group among the plurality of second pads is connected to each second electrode of the plurality of first conductive transistors, and
wherein each pad of a fourth group among the plurality of second pads is connected to each second electrode of the plurality of second conductive transistors.

4. The sub word line driver of claim 3, wherein each of the plurality of first conductive transistors is one of a PMOS transistor and an NMOS transistor, and
wherein each of the plurality of second conductive transistors is the other of the PMOS transistor and the NMOS transistor.

5. The sub word line driver of claim 3, wherein the first electrode of each of the plurality of first conductive transistors and second conductive transistors is a source electrode, and
wherein the second electrode of each of the plurality of first conductive transistors and second conductive transistors is a drain electrode.

6. A semiconductor device comprising:
a plurality of sub arrays; and
a plurality of sub word line drivers each disposed between the plurality of sub arrays, each of the plurality of sub word line drivers including
a first layer including a plurality of first pads arranged in a line of a first direction, a plurality of second pads disposed in a line of the first direction, and two first word lines disposed twisted twice in the first direction between the plurality of first pads and the plurality of second pads, each of the two first word lines being connected to a corresponding pad among the plurality of second pads, and
a second layer formed at a lower part of the first layer, the second layer including a plurality of third pads, each of the plurality of third pads being disposed at a position corresponding to a pad from among one of the plurality of first pads and the plurality of second pads.

7. The semiconductor device of claim 6, wherein the first layer further includes
a plurality of fourth pads each formed in an opposite position to each of the plurality of first pads, and
two second word lines disposed twisted twice in the first direction between the plurality of second pads and the plurality of fourth pads,
wherein the second layer further includes
a plurality of fifth pads each formed at positions corresponding to each of the plurality of fourth pads, and
wherein each of the two second word lines is connected to a corresponding pad among the plurality of second pads.

8. The semiconductor device of claim 6, wherein the plurality of third pads are each connected to at least one transistor from among a plurality of first conductive transistors and a plurality of second conductive transistors,
wherein each pad of a first group among the plurality of first pads is connected to a first electrode of each of the plurality of first conductive transistors via a corresponding one of the plurality of third pads,
wherein each pad of a second group among the plurality of first pads is connected to a first electrode of each of the plurality of second conductive transistors via a corresponding one of the plurality of third pads,
wherein each pad of a third group among the plurality of second pads is connected to a second electrode of each of the plurality of first conductive transistors, and
wherein each pad of a fourth group among the plurality of second pads is connected to a second electrode of each of the plurality of second conductive transistors.

9. (canceled)

10. (canceled)

11. A semiconductor system comprising:
the semiconductor device of claim 6; and
a processor for controlling an operation of the semiconductor device.

12. The semiconductor system of claim 11, wherein the first layer includes
a plurality of fourth pads each formed in an opposite position to each of the plurality of first pads, and
two second word lines disposed twisted twice in the first direction between the plurality of second pads and the plurality of fourth pads,
wherein the second layer includes
a plurality of fifth pads each formed at positions corresponding to each of the plurality of fourth pads, and
wherein each of the two second word lines is connected to a corresponding pad among the plurality of second pads.

13. The semiconductor system of claim 11, wherein the plurality of third pads are each connected to at least one transistor from among a plurality of first conductive transistors and a plurality of second conductive transistors,
wherein each pad of a first group among the plurality of first pads is connected to a first electrode of each of a plurality of first conductive transistors via a corresponding one of the plurality of third pads,
wherein each pad of a second group among the plurality of first pads is connected to a first electrode of each of a plurality of second conductive transistors via a corresponding one of the plurality of third pads,
wherein each pad of a third group among the plurality of second pads is connected to a second electrode of each of the plurality of first conductive transistors,
wherein each pad of a fourth group among the plurality of second pads is connected to a second electrode of each of the plurality of second conductive transistors.

14. (canceled)

15. (canceled)

16. The semiconductor system of claim 11, wherein the semiconductor system is a mobile communication device.

17. A memory module comprising:
the semiconductor device of claim 6, and
a semiconductor substrate where the semiconductor device is mounted.

18. A semiconductor system comprising:
the memory module of claim 17;
a board including a socket where the memory module may be inserted; and
a processor for controlling an operation of the semiconductor device through the socket.

19. The semiconductor system of claim 18, wherein the memory module is at least one of a single in-line memory module (SIMM) or a dual in-line memory module (DIMM).

20. (canceled)

21. A sub word line driver comprising:
a first layer including
a plurality of first pads disposed in a first line of a first direction,
a plurality of second pads arranged in a second line of the first direction, and
at least two first word lines arranged along the first direction and in between the plurality of first pads and the plurality of second pads, the at least two first word lines being twisted at least once at a position in between the plurality of first pads and the plurality of second pads.

22. The sub word line driver of claim 21, wherein
the at least two first word lines are twisted such that (1) for a first portion of a length of the at least two first word lines, a first one of the at least two first word lines is in between the second pads and a second one of the at least two first word lines, and (2) for a second portion of the length of the at least two first word lines, the second one of the at least two first word lines is in between the second pads and the first one of the at least two first word lines.

23. The sub word line driver of claim 21, wherein
the at least two first word lines are each connected to at least one corresponding pad among the plurality of second pads.

24. The sub word line driver of claim 21 further comprising:
a second layer formed at a lower part of the first layer, the second layer including a plurality of third pads, each of the plurality of third pads being disposed at a position corresponding to one of the first and second pads of the first layer.

25. The sub word line driver of claim 24 wherein the first layer further comprises:
a plurality of fourth pads in a third line of the first direction; and
at least two second word lines arranged along the first direction and in between the plurality of second pads and the plurality of fourth pads, the at least two second word lines being twisted at least once.
